(19) United States
(12) Patent Application Publication
(10) Pub. No.: US 2026/0130198 A1
(43) Pub. Date: May 7, 2026

(54) SEMICONDUCTOR DEVICE AND METHOD FOR ANALYZING A FAILURE OF THE SAME

(71) Applicant: Samsung Electronics Co., Ltd., Suwon-si (KR)

(72) Inventors: Myungjin CHUNG, Suwon-si (KR); Jinkyu KIM, Suwon-si (KR); Eunguk CHUNG, Suwon-si (KR); Keun Hwi CHO, Suwon-si (KR); Suhaeng HEO, Suwon-si (KR)

(73) Assignee: Samsung Electronics Co., Ltd., Suwon-si (KR)

(21) Appl. No.: 19/248,115

(22) Filed: Jun. 24, 2025

(30) Foreign Application Priority Data
Nov. 1, 2024 (KR) 10-2024-0153290

(51) Int. Cl. H01L 23/522; G01N 25/72; H01L 23/00; H01L 23/528; H10D 30/00; H10D 30/43; H10D 62/10; H10D 62/13; H10D 84/83

(52) U.S. Cl. CPC H10W 20/42; G01N 25/72; H10D 30/43; H10D 30/503; H10D 62/121; H10D 62/151; H10D 84/832; H10W 20/427; H10W 20/43; H10W 20/435; H10W 20/498; H10D 62/102; H10W 72/234; H10W 72/242; H10W 90/734

(57) ABSTRACT

A semiconductor device includes a substrate having a front surface and a rear surface. The device includes a first transistor disposed on the front surface of the substrate and including a first gate electrode and first source/drain patterns disposed adjacent to the first gate electrode. The device includes a front surface dummy stack structure disposed on the first transistor and electrically floated, the front surface dummy stack structure extending from a lower end to an upper end, the lower end being spaced apart from the first transistor. The front surface dummy stack structure includes alternately stacked front surface dummy vias front surface dummy wires that overlap the first gate electrode such that heat generated in the first transistor is transferred to the upper end of the front surface dummy stack structure through the plurality of front surface dummy vias and the plurality of front surface dummy wires.

### CROSS-REFERENCE TO RELATED APPLICATIONS

This U.S. non-provisional patent application claims priority under 35 U.S.C. § 119 of Korean Patent Application No. 10-2024-0153290, filed on Nov. 1, 2024, the entire contents of which are hereby incorporated by reference.

### FIELD

The present disclosure relates to a semiconductor device and a method for analyzing a failure of the same.

### BACKGROUND

A semiconductor device may include an integrated circuit composed of metal-oxide-semiconductor field effect transistors (MOSFETs). As a size and a design rule of the semiconductor device gradually decrease, scaling down of the MOSFETs is being accelerated. When the sizes of the MOSFETs decrease, a defect or failure of the semiconductor device may occur. Failure analysis is widely used in the semiconductor industry, and the defects of the semiconductor devices such as integrated circuits may be detected. However, as designs of the semiconductor devices become more complicated, defect detection accuracy is being deteriorated.

### SUMMARY

The present disclosure provides a semiconductor device in which a failure thereof can be easily analyzed.

The present disclosure also provides a method for analyzing a failure of a semiconductor device with improved consistency.

An embodiment consistent with the present disclosure provides a semiconductor device including a substrate including a front surface and a rear surface opposed to each other, a first transistor disposed on the front surface of the substrate, and including a first gate electrode and first source/drain patterns adjacent to both sides thereof, and a front surface dummy stack structure located on the first transistor, and electrically floated, wherein the front surface dummy stack structure includes front surface dummy vias and front surface dummy wires alternately stacked, and the front surface dummy vias and the front surface dummy wires that constitute the front surface dummy stack structure vertically overlap the first gate electrode.

In an embodiment consistent with the present disclosure, a semiconductor device includes a substrate including a front surface and a rear surface opposed to each other, a first transistor disposed on the front surface of the substrate, and including a first gate electrode and first source/drain patterns adjacent to both sides thereof, a first power wire disposed on the rear surface of the substrate, and connected to one of the first source/drain patterns, and a rear surface dummy stack structure disposed on the rear surface of the substrate, and electrically floated, wherein the rear surface dummy stack structure includes rear surface dummy vias and rear surface dummy wires alternately stacked, and the rear surface dummy vias and the rear surface dummy wires that constitute the rear surface dummy stack structure vertically overlap the first gate electrode.

In an embodiment consistent with the present disclosure, a semiconductor device includes a substrate including a front surface and a rear surface opposed to each other, a first flip-flop circuit and a second flip-flop circuit disposed on the front surface of the substrate, a first transistor disposed on the front surface of the substrate, including a first gate electrode and first source/drain patterns adjacent to both sides thereof, and included in the first flip-flop circuit, a second transistor disposed on the front surface of the substrate, including a second gate electrode and second source/drain patterns adjacent to both sides thereof, and included in the second flip-flop circuit, a front surface dummy stack structure located on the first transistor, and electrically floated, a first wiring structure disposed on the front surface of the substrate, and connected to one of the first source/drain patterns and the first gate electrode, a first power wire disposed on the rear surface of the substrate, and connected to one of the second source/drain patterns, a rear surface dummy stack structure disposed on the rear surface of the substrate, and electrically floated, and a second wiring structure disposed on the rear surface of the substrate, and connected to the first power wire, wherein the front surface dummy stack structure includes front surface dummy vias and front surface dummy wires alternately stacked, the front surface dummy vias and the front surface dummy wires that constitute the front surface dummy stack structure vertically overlap the first gate electrode, the rear surface dummy stack structure includes rear surface dummy vias and rear surface dummy wires alternately stacked, and the rear surface dummy vias and the rear surface dummy wires that constitute the rear surface dummy stack structure vertically overlap the second gate electrode.

In an embodiment consistent with the present disclosure, a method for analyzing a failure of a semiconductor device includes manufacturing a semiconductor device including a front surface dummy stack structure disposed on a substrate and a rear surface dummy stack structure disposed on a lower portion of the substrate, finding out a temperature of an upper surface of the semiconductor device with a thermal imaging camera, detecting a temperature change of an upper end of the front surface dummy stack structure according to time by irradiating the upper end of the front surface dummy stack structure with first laser, finding out a temperature of a lower surface of the semiconductor device with the thermal imaging camera, and detecting a temperature change of a lower end of the rear surface dummy stack structure according to time by irradiating the lower end of the rear surface dummy stack structure with second laser.

### BRIEF DESCRIPTION OF THE FIGURES

The accompanying drawings are included to provide a further understanding of the present disclosure, and are incorporated in and constitute a part of this specification. The drawings illustrate embodiments consistent with the present disclosure and, together with the description, serve to explain principles of the present disclosure. In the drawings:

FIG. 1 is a cross-sectional view of a semiconductor device consistent with embodiments of the present disclosure;

FIGS. 2A to 2C are enlarged diagrams of ‘P1’ of FIG. 1 consistent with embodiments of the present disclosure;

FIG. 3 is a cross-sectional view of a first transistor consistent with embodiments of the present disclosure;

FIGS. 4A and 4B are enlarged diagrams of ‘P2’ of FIG. 1 consistent with embodiments of the present disclosure;

FIGS. 5A and 5B are plan views of a portion of a semiconductor device consistent with embodiments of the present disclosure;

FIGS. 6A to 6D are plan views of a portion of a semiconductor device consistent with embodiments of the present disclosure;

FIGS. 7A and 7B are conceptual diagrams of a semiconductor device consistent with embodiments of the present disclosure;

FIGS. 8A and 8B are conceptual diagrams of a semiconductor device consistent with embodiments of the present disclosure;

FIG. 9 is a flowchart illustrating a method for analyzing a failure of a semiconductor device consistent with embodiments of the present disclosure; and

FIG. 10 is a schematic diagram illustrating a method for analyzing a failure of a semiconductor device consistent with embodiments of the present disclosure.

### DETAILED DESCRIPTION

Hereinafter, embodiments of the present disclosure will be described in more detail with reference to the accompanying drawings so as to more specifically describe the present disclosure. In the present specification, terms, representing a sequence, such as first or second are used so as to distinguish components doing the same/similar functions, and the terms may be changed according to the sequence in which the components are mentioned

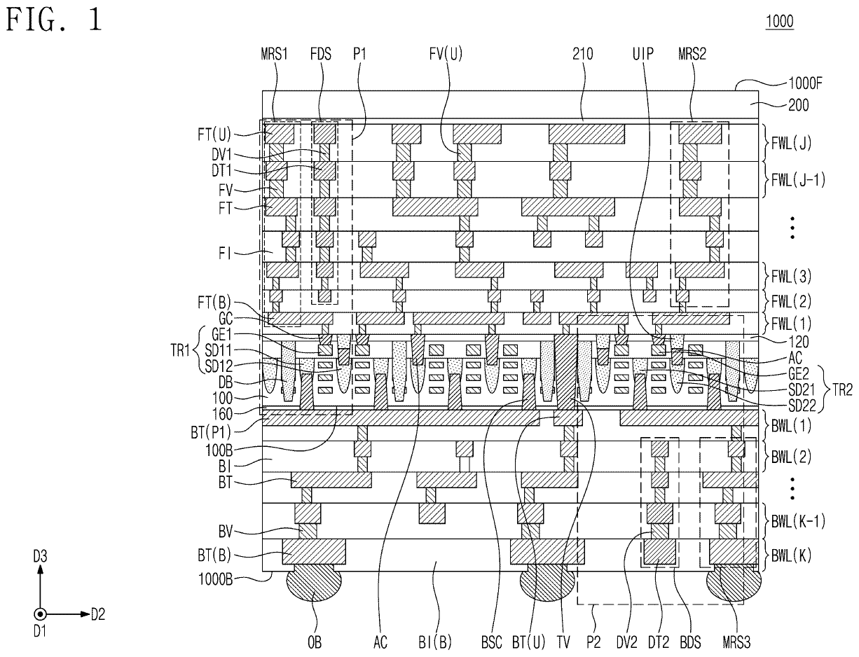

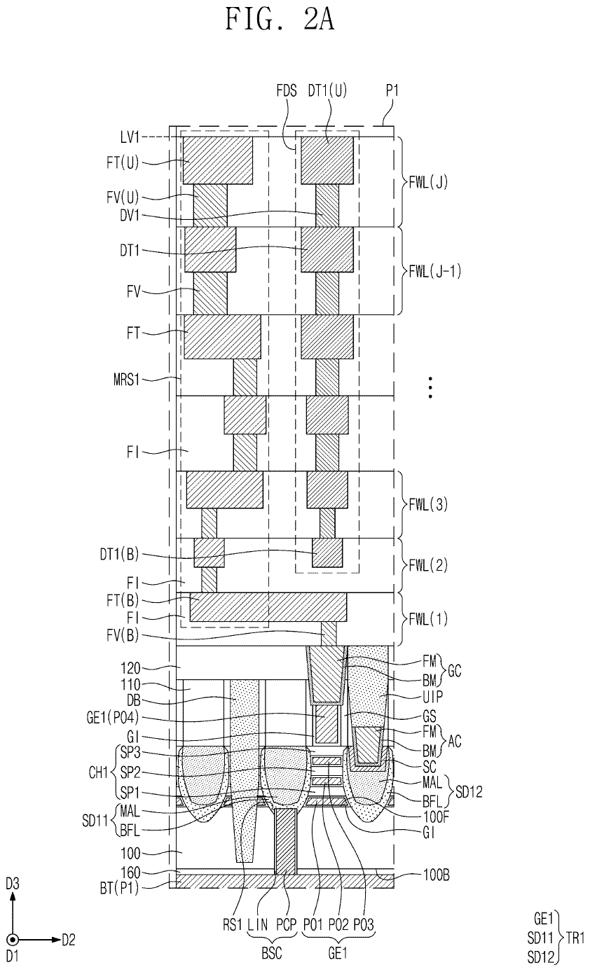

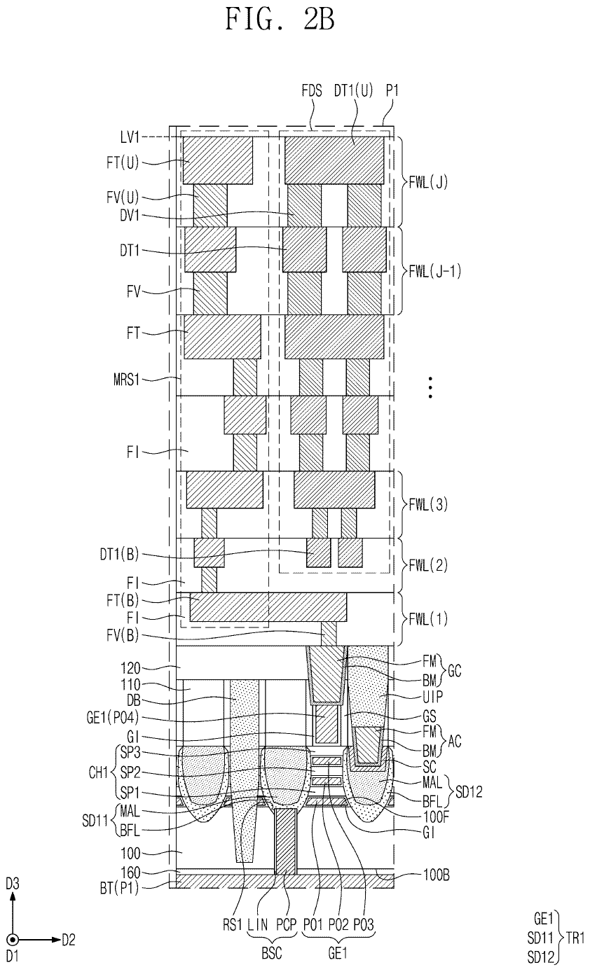

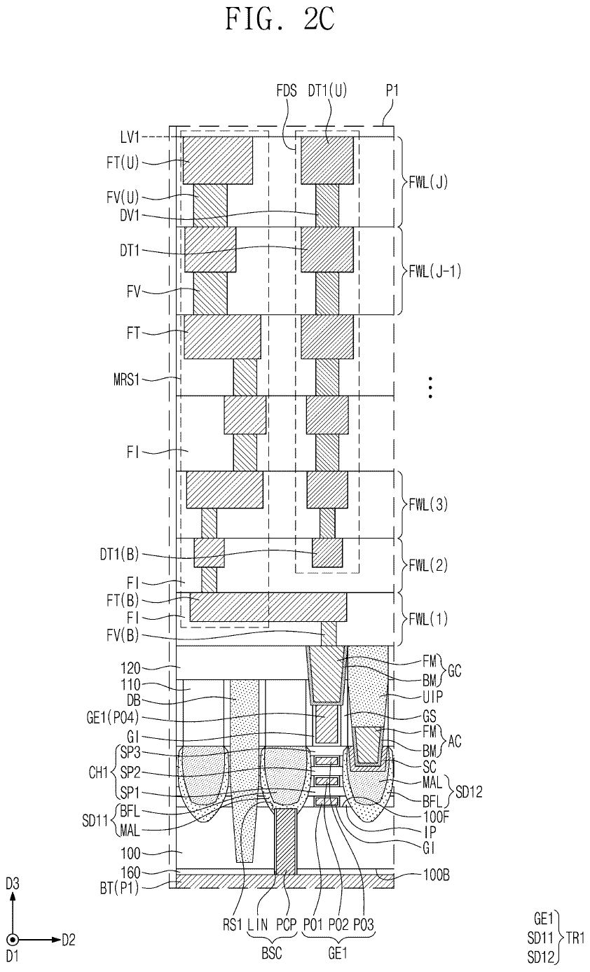

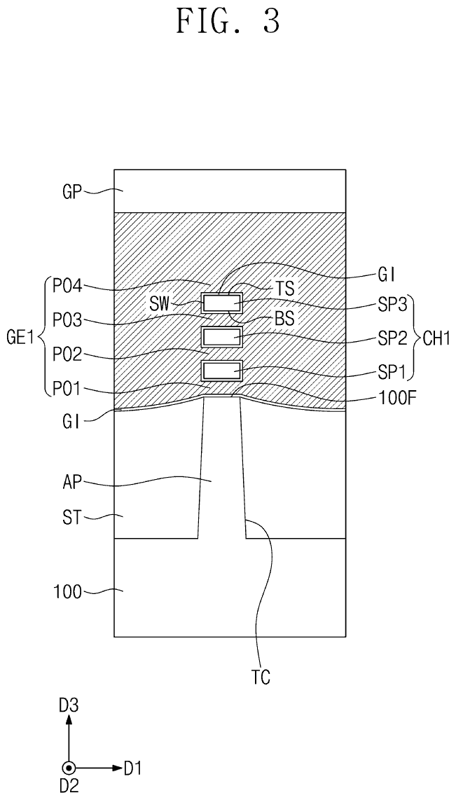

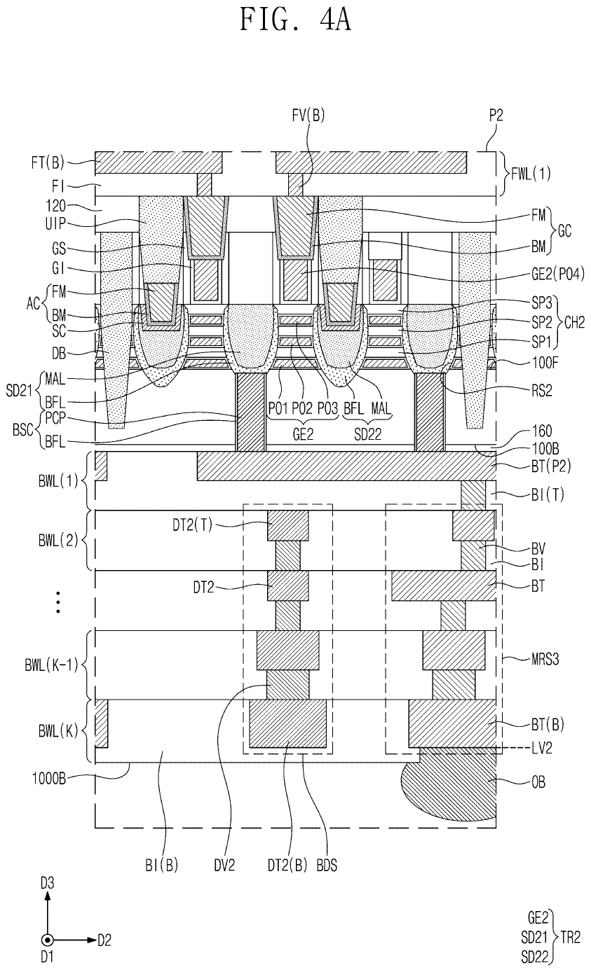

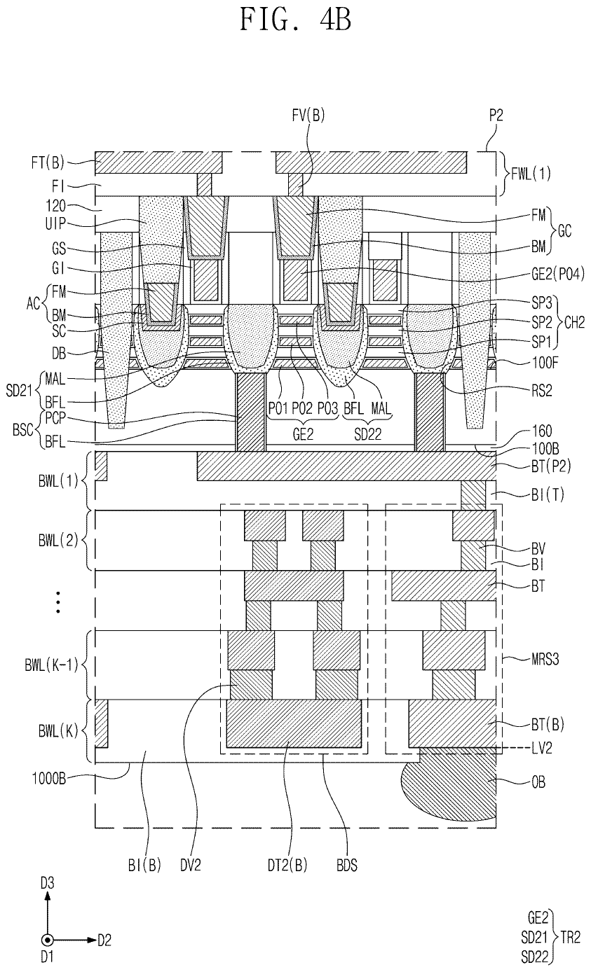

FIG. 1 is a cross-sectional view of a semiconductor device consistent with embodiments of the present disclosure. FIGS. 2A to 2C are enlarged diagrams of ‘P1’ of FIG. 1 consistent with embodiments of the present disclosure. FIG. 3 is a cross-sectional view of a first transistor consistent with embodiments of the present disclosure. FIG. 3 illustrates a cross-section that cuts a first gate electrode GE1 of a first transistor TR1 of FIG. 1 in a length direction D1. FIGS. 4A and 4B are enlarged diagrams of ‘P2’ of FIG. 1 consistent with embodiments of the present disclosure.

Referring to FIGS. 1, 2A, and 4A, a semiconductor device 1000 according to one exemplary embodiment includes a substrate 100. The substrate 100 may be a semiconductor substrate including silicon, germanium, silicon-germanium or the like, a compound semiconductor substrate, or an insulating substrate composed of an insulating material such as silicon oxide. The substrate 100 may include a front surface 100F and a rear surface 100B opposed to each other.

Transistors TR1 and TR2 are disposed on the front surface 100F of the substrate 100. The first transistor TR1 may include the first gate electrode GE1 and eleventh and twelfth source/drain patterns SD11 and SD12 adjacent to both sides thereof. A second transistor TR2 may include a second gate electrode GE2 and twenty first and twenty second source/drain patterns SD21 and SD22 adjacent to both sides thereof.

The transistors TR1 and TR2 have a multi-bridge-channel FET (MBCFET) shape, but the embodiments of the present disclosure are not limited thereto, and the transistors TR1 and TR2 may have a shape of a planar FET, a FinFET, a vertical FET, a buried channel array transistor (BCAT) or a gate-all-around FET (GAAFET).

An active pattern AP may be defined on the substrate 100 by a trench TC. The active pattern AP may be a vertically protruding part as a portion of the substrate 100. The active pattern AP may be provided in plurality. Some of the active patterns AP may be provided in a p-type MOSFET (PMOSFET) region, and others of the active patterns AP may be provided in a n-type MOSFET (NMOSFET) region.

An element separation layer ST may fill the trench TC. The element separation layer ST may include a silicon oxide layer. The element separation layer ST may not cover first and second channel patterns CH1 and CH2 to be described later.

Referring to FIG. 3, the first channel pattern CH1 may be provided on one among the active patterns AP. The second channel pattern CH2 may be provided on another one among the active patterns AP. Each of the first channel pattern CH1 and the second channel pattern CH2 may include a first semiconductor pattern SP1, a second semiconductor pattern SP2 and a third semiconductor pattern SP3 sequentially stacked. The first to third semiconductor patterns SP1, SP2 and SP3 may be spaced apart from each other in a vertical direction (that is, in a third direction D3).

Referring to FIGS. 2A and 3, each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. Each of the first to third semiconductor patterns SP1, SP2, and SP3 may be a nano-sheet.

Referring to FIG. 2A, the eleventh and twelfth source/drain patterns SD11 and SD12 may be provided on both sides of the first channel pattern CH1. A plurality of first recesses RS1 may be formed on the substrate 100. The eleventh and twelfth source/drain patterns SD11 and SD12 may be respectively provided in the first recesses RS1. The eleventh and twelfth source/drain patterns SD11 and SD12 may be first conductive type (for example, a P-type) impurity regions. The stacked first to third semiconductor patterns SP1, SP2, and SP3 of the first channel pattern CH1 may connect the eleventh and twelfth source/drain patterns SD11 and SD12 each other.

Referring to FIG. 4A, the twenty first and twenty second source/drain patterns SD21 and SD22 may be provided on both sides of the second channel pattern CH2. A plurality of second recesses RS2 may be formed on the substrate 100. The twenty first and twenty second source/drain patterns SD21 and SD22 may be respectively provided in the second recesses RS2. The twenty first and twenty second source/drain patterns SD21 and SD22 may be first conductive type (for example, a P-type) impurity regions. The stacked first to third semiconductor patterns SP1, SP2, and SP3 of the second channel pattern CH2 may connect the twenty first and twenty second source/drain patterns SD21 and SD22 each other.

Referring to FIG. 3, the first gate electrode GE1 extending across the first channel pattern CH1 in a first direction D1 may be provided. Referring to FIG. 4A, the second gate electrode GE2 may extend across the second channel pattern CH2 in the first direction D1. The first and second gate electrodes GE1 and GE2 may respectively vertically overlap the first and second channel patterns CH1 and CH2.

Referring to FIG. 3, each of the first and second gate electrodes GE1 and GE2 may include a first inner electrode PO1 interposed between the active pattern AP and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 3, each of the first and second gate electrodes GE1 and GE2 may be provided on an upper surface TS, a bottom surface BS and both sidewalls SW of each of the first to third semiconductor patterns SP1, SP2, and SP3.

The first and second transistors TR1 and TR2 disclosed in FIGS. 2A, 2B, 4A and 4B may have a PMOSFET structure. In this case, each of the eleventh and twelfth source/drain patterns SD11 and SD12 and the twenty first and twenty second source/drain patterns SD21 and SD22 may include at least one of Si, SiGe, SiGeB, Ge, InSb, GaSb, or InGaSb.

Specifically, referring to FIGS. 2A and 4A, the eleventh and twelfth source/drain patterns SD11 and SD12 and the twenty first and twenty second source/drain patterns SD21 and SD22 may be epitaxial patterns formed in a selective epitaxial growth (SEG) process. For example, an upper surface of each of the eleventh and twelfth source/drain patterns SD11 and SD12 and the twenty first and twenty second source/drain patterns SD21 and SD22 may be substantially located at the same level as an upper surface of the third semiconductor pattern SP3. For another example, each of the eleventh and twelfth source/drain patterns SD11 and SD12 and the twenty first and twenty second source/drain patterns SD21 and SD22 may have a higher upper surface than the third semiconductor pattern SP3.

The eleventh and twelfth source/drain patterns SD11 and SD12 may include a semiconductor element (for example, SiGe) having a greater lattice parameter than the substrate 100. Accordingly, the eleventh and twelfth source/drain patterns SD11 and SD12 may supply a compressive stress to the first channel pattern CH1 therebetween.

Each of the eleventh and twelfth source/drain patterns SD11 and SD12 may include a buffer layer BFL and a main layer MAL on the buffer layer BFL. Referring to FIGS. 2A and 4A, the buffer layer BFL may cover inner sidewalls of the first recess RS1 and the second recess RS2. According to an embodiment, the buffer layer BFL may substantially have a conformal thickness. According to another embodiment, the thickness of the buffer layer BFL may become smaller in an upward direction. The buffer layer BFL may have a U shape along a profile of the first recess RS1.

The main layer MAL may fill most of the remaining region of the first recess RS1 and the second recess RS2 except for the buffer layer BFL. The main layer MAL may have a greater volume than the buffer layer BFL. Each of the buffer layer BFL and the main layer MAL may include silicon-germanium (SiGe). Specifically, the buffer layer BFL may contain germanium (Ge) at a relatively lower concentration. According to another embodiment consistent with the present disclosure, the buffer layer BFL may contain only silicon (Si) without germanium (Ge). The buffer layer BFL may have a germanium (Ge) concentration of 0 at % to about 10 at %.

The main layer MAL may contain germanium (Ge) at a relatively higher concentration. For example, the main layer MAL may have a germanium (Ge) concentration of about 30 at % to about 70 at %. The main layer MAL may have the germanium (Ge) concentration increasing in the third direction D3. For example, the main layer MAL adjacent to the buffer layer BFL may have the germanium (Ge) concentration of about 40 at %, but an upper portion of the main layer MAL may have the germanium (Ge) concentration of about 60 at %.

Each of the buffer layer BFL and the main layer MAL may include an impurity (for example, boron, gallium, or indium) that causes the eleventh and twelfth source/drain patterns SD11 and SD12 to have a P-type. Each of the buffer layer BFL and the main layer MAL may have an impurity concentration of about 1E18 atom/cm³ to about 5E22 atom/cm³. The main layer MAL may have a greater impurity concentration than the buffer layer BFL.

The buffer layer BFL may prevent stacking faults between the substrate 100 and the main layer MAL, and the first to third semiconductor patterns SP1, SP2, and SP3 and the main layer MAL. When the stacking fault occurs, channel resistance may increase. The buffer layer BFL may protect the main layer MAL in a process of manufacturing the semiconductor device 1000.

Alternatively, referring to FIG. 2C, the first transistor TR1 may have an NMOSFET structure. The second transistor TR2 may have the NMOSFET structure. In this case, each of the eleventh and twelfth source/drain patterns SD11 and SD12 and the twenty first and twenty second source/drain patterns SD21 and SD22 may include at least one of Si, SiP, SiC, SiPC, InP, GaAs, AlAs, InAs, InAlAs, or InGaAs.

Referring to FIG. 2C as a specific example, each of the eleventh and twelfth source/drain patterns SD11 and SD12 and the twenty first and twenty second source/drain patterns SD21 and SD22 may include the same semiconductor element (for example, Si) as the substrate 100. Each of the eleventh and twelfth source/drain patterns SD11 and SD12 and the twenty first and twenty second source/drain patterns SD21 and SD22 may further include an N-type impurity (for example, phosphorus, arsenic, or antimony). The twenty first and twenty second source/drain patterns SD21 and SD22 may have an impurity concentration of about 1E18 atom/cm³ to about 5E22 atom/cm³.

Referring to FIG. 2C, when the first transistor TR1 and the second transistor TR2 have the NMOSFET structure, inner spacers IP may be respectively interposed between the eleventh and twelfth source/drain patterns SD11 and SD12 and the first to third inner electrodes PO1, PO2, and PO3 of the first gate electrode GE1. Although not shown, the inner spacers IP may be respectively interposed between the twenty first and twenty second source/drain patterns SD21 and SD22 and the first to third inner electrodes PO1, PO2, and PO3 of the second gate electrode GE2. The inner spacers IP may be in direct contact with the eleventh and twelfth source/drain patterns SD11 and SD12. The inner spacers IP may be in direct contact with the twenty first and twenty second source/drain patterns SD21 and SD22. Each of the first to third inner electrodes PO1, PO2, and PO3 of the first gate electrode GE1 may be spaced apart from the eleventh and twelfth source/drain patterns SD11 and SD12 by the inner spacer IP. Each of the first to third inner electrodes PO1, PO2, and PO3 of the second gate electrode GE2 may be spaced apart from the twenty first and twenty second source/drain patterns SD21 and SD22 by the inner spacer IP.

Referring to FIGS. 2A and 4A, a pair of gate spacers GS may be respectively disposed on both sidewalls of the outer electrode PO4 of each of the first and second gate electrodes GE1 and GE2. The gate spacers GS may extend in the first direction D1 along each of the first and second gate electrodes GE1 and GE2. Upper surfaces of the gate spacers GS may be higher than an upper surface of each of the first and second gate electrodes GE1 and GE2. The upper surfaces of the gate spacers GS may be coplanar with an upper surface of a first interlayered insulating layer 110 to be described later. The gate spacers GS may have a single-layered or multi-layered structure of at least one of SiO₂, SiON, SiCN, SiCON, or SiN.

A gate capping pattern GP may be provided on each of the first and second gate electrodes GE1 and GE2. The gate capping pattern GP may extend in the first direction D1 along each of the first and second gate electrodes GE1 and GE2. The gate capping pattern GP may include a material having etching selectivity with respect to first and second interlayered insulating layers 110 and 120 to be described later. Specifically, the gate capping pattern GP may include at least one of SiON, SiCn, SiCON, or SiN.

Gate insulating layers GI may be respectively interposed between the first and second gate electrodes GE1 and GE2 and the first and second channel patterns CH1 and CH2. The gate insulating layer GI may cover an upper surface TS, a bottom surface BS and both sidewalls SW of each of the first to third semiconductor patterns SP1, SP2, and SP3. Referring to FIG. 3, the gate insulating layer GI may cover an upper surface of the element separation layer ST under each of the first and second gate electrodes GE1 and GE2.

According to an embodiment consistent with the present disclosure, the gate insulating layer GI may include a silicon oxide layer, a silicon oxynitride layer, and/or a high dielectric layer. The high dielectric layer may include a high dielectric material having a greater dielectric constant than a silicon oxide layer. For example, the high dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobite.

Each of the first and second gate electrodes GE1 and GE2 may include a first metal pattern, and a second metal pattern on the first metal pattern. The first metal pattern may be provided on the gate insulating layer GI to be adjacent to the first to third semiconductor patterns SP1, SP2, and SP3. The first metal pattern may include a work-function metal that controls a threshold voltage of a transistor. A targeted threshold voltage of the transistor may be achieved by controlling a thickness and a composition of the first metal pattern. For example, the first to third inner electrodes PO1, PO2, and PO3 of each of the first and second gate electrodes GE1 and GE2 may be composed of the first metal pattern, which is the work-function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include lower resistant metal than the first metal pattern. For example, the second metal pattern may include at least one metal selected from the group consisting of tungsten (W), aluminum (Al), titanium (Ti), and tantalum (Ta). For example, the outer electrode PO4 of each of the first and second gate electrodes GE1 and GE2 may include the first metal pattern and the second metal pattern on the first metal pattern.

The first interlayered insulating layer 110 may be provided on the substrate 100. The first interlayered insulating layer 110 may cover the gate spacers GS and the eleventh and twelfth source/drain patterns SD11 and SD12. An upper surface of the first interlayered insulating layer 110 may be substantially coplanar with an upper surface of the gate spacer GS and an upper surface of the gate capping pattern GP. The second interlayered insulating layer 120 covering the gate capping pattern GP may be disposed on the first interlayered insulating layer 110. For example, the first and second interlayered insulating layers 110 and 120 may include a silicon oxide layer.

Separation structures DB may be provided to separate cell regions. The cell regions may be regions for various logic cells such as a single height cell SHC or a double height cell DHC, or regions for tab cells. The logic cell may mean a logic element (for example, AND, OR, XOR, XNOR, an inverter or the like) that performs a specific function. That is, the logic cell may include transistors for constituting the logic element, and wires connecting the transistors each other. The tab cell may not include the logic element unlike the logic cell. In other words, the tab cell may be a kind of dummy cell that performs a function of applying a voltage to a power wire, but does not perform a circuit function.

The separation structure DB may extend parallel to the first and second gate electrodes GE1 and GE2 in the first direction D1. A pitch between the separation structure DB and the gate electrodes GE1 and GE2 adjacent thereto may be the same as a pitch between the first and second gate electrodes GE1 and GE2.

The separation structure DB may penetrate the first interlayered insulating layer 110 to extend into the inside of the substrate 100. The separation structure DB may electrically separate an active region of one cell region from an active region of another cell region adjacent thereto.

Referring to FIGS. 1 and 2A, an active contact AC connected to at least one among the source/drain patterns SD11, SD12, SD21 and SD22 may be provided. On a plan view, the active contact AC may have a shape of a bar extending in the first direction D1. The active contact AC may penetrate the first and second interlayered insulating layers 110 and 120.

The active contact AC may be a self-aligned contact. In other words, the active contact AC may be formed self-aligned using the gate capping pattern GP and the gate spacer GS. For example, the active contact AC may at least partially cover a sidewall of the gate spacer GS.

A metal-semiconductor compound layer SC, for example, a silicide layer may be interposed between the active contact AC and one of the source/drain patterns SD11, SD12, SD21, and SD22. The active contact AC may be electrically connected to one of the source/drain patterns SD11, SD12, SD21, and SD22 through the metal-semiconductor compound layer SC. For example, the metal-semiconductor compound layer SC may include at least one of titanium-silicide, tantalum-silicide, tungsten-silicide, nickel-silicide, or cobalt-silicide.

Gate contacts GC penetrating the second interlayered insulating layer 120 and the gate capping pattern GP to be respectively electrically connected to the gate electrodes GE may be provided. The gate contact GC may be freely disposed on the gate electrodes GE without positional limitation.

An upper portion of the active contact AC adjacent to the gate contact GC may be filled with an upper insulating pattern UIP. A bottom surface of the upper insulating pattern UIP may be lower than a bottom surface of the gate contact GC. In other words, an upper surface of the active contact AC adjacent to the gate contact GC may be lower than the bottom surface of the gate contact GC by the upper insulating pattern UIP. Accordingly, limitation of a short circuit that occurs by a contact of the gate contact GC and the active contact AC adjacent thereto may be prevented.

Each of the active contact AC and the gate contact GC may include a conductive pattern FM and a barrier pattern BM surrounding the conductive pattern FM. For example, the conductive pattern FM may include at least one of aluminum, copper, tungsten, molybdenum, or cobalt. The barrier pattern BM may cover sidewalls and a bottom surface of the conductive pattern FM. The barrier pattern BM may include a metal layer and/or metal nitride layer. The metal layer may include at least one of titanium, tantalum, tungsten, nickel, cobalt, or platinum. The metal nitride layer may include at least one of a titanium nitride (TiN) layer, a tantalum nitride (TaN) layer, a tungsten nitride (WN) layer, a nickel nitride (NiN) layer, a cobalt nitride (CON) layer, or a platinum nitride (PtN) layer.

Referring to FIGS. 1 and 2A, front surface wiring layers FWL are sequentially stacked on the second interlayered insulating layer 120. The front surface wiring layers FWL may include first to j-th front surface wiring layers FWL(1) to FWL(J). Each of the front surface wiring layers FWL may include a front surface insulating layer FI, and front surface vias FV and front surface wires FT disposed therein. The J may be a natural number equal to or greater than 3.

The front surface insulating layer FI may have a single-layered or multi-layered structure of at least one of SiO₂, SIN, SiON, SiCN, or SiOCH. Each of the front surface vias FV and the front surface wires FT may include metal such as tungsten, copper, aluminum, titanium, or tantalum.

The front surface wires FT belonging to an odd-numbered front surface wiring layer (FWL(1), FWL(3) . . . ) among the front surface wiring layers FWL may extend along a second direction D2. The front surface wires FT belonging to an even-numbered front surface wiring layer (FWL(2), FWL(4) . . . ) among the front surface wiring layers FWL may extend along the first direction D1 crossing the second direction D2. Some of the front surface wires FT and the front surface vias FV may apply an electrical signal to the gate contact GC and the active contact AC or receive the electrical signal from the gate contact GC and the active contact AC. A lowermost front surface wire FT(B) among the front surface wires FT may have a smaller width, height and/or pitch than an uppermost front surface wire FT(U). A lowermost front surface via FV(B) among the front surface vias FV may have a smaller width, height and/or pitch than an uppermost front surface via FV(U). The lowermost front surface wire FT(B) in a lowermost first front surface wiring layer FWL(1) may have a greater wire density per unit area than the uppermost front surface wire FT(U) in an uppermost j-th front surface wiring layer FWL(J). An upper surface of the uppermost front surface wire FT(U) among the front surface wires FT may have a first level LV1.

Some of the front surface wires FT and the front surface vias FV may constitute a first wiring structure MRS1 of FIGS. 1, and 2A to 2C. The first wiring structure MRS1 may be connected to the first gate electrode GE1 of the first transistor TR1. The lowermost front surface wire FT(B), among the front surface wires FT, that constitutes the first wiring structure MRS1 may overlap the first gate electrode GE1, and may extend in the second direction D2 or an opposite direction of the second direction D2. In some embodiments, the first wiring structure MRS1 may be connected to one of the eleventh and twelfth source/drain patterns SD11 and SD12.

Others of the front surface wires FT and the front surface vias FV may constitute a second wiring structure MRS2 of FIG. 1. The second wiring structure MRS2 may be connected to the second gate electrode GE2 of the second transistor TR2. The lowermost front surface wire FT(B), among the front surface wires FT, that constitutes the second wiring structure MRS2 may overlap the second gate electrode GE2, and may extend in the second direction D2 or an opposite direction of the second direction D2.

Referring to FIG. 2A, a front surface dummy stack structure FDS may be disposed on the front surface 100F of the substrate 100. The front surface dummy stack structure FDS may include front surface dummy wires DT1 and front surface dummy vias DV1 alternately stacked. The front surface dummy wires DT1 and the front surface dummy vias DV1 may vertically overlap each other. An upper surface of an uppermost front surface dummy wire DT1(U), among the front surface dummy wires DT1, that constitutes the front surface dummy stack structure FDS may have the first level LV1. That is, the upper surface of the uppermost front surface dummy wire DT1(U) may be located at the same level LV1 as the upper surface of the uppermost front surface wire FT(U). Ones, located at the same level, among the front surface dummy wires DT1 and the front surface wires FT may have the same width, and/or height as each other, and may be formed of the same material. Ones, located at the same level, among the front surface dummy vias DV1 and the front surface vias FV may have the same width and/or height as each other, and may be formed of the same material.

The front surface dummy stack structure FDS may be electrically floated. The front surface dummy stack structure FDS is not connected to the transistors TR1 and TR2 and the front surface wires FT. A lowermost front surface dummy wire DT1(B) among the front surface dummy wires DT1 that constitute the front surface dummy stack structure FDS may be spaced apart from a lowermost front surface wire FT(B) among the front surface wires FT in a vertical direction (that is, the third direction D3), and the (only one-layered) front surface insulating layer FI may be interposed between the lowermost front surface dummy wire DT1(B) and the lowermost front surface wire FT(B). In some embodiments, the uppermost front surface dummy wire DT1(U) may have a larger width, height and/or pitch than the lowermost front surface dummy wire DT1(B).

Referring to FIG. 2A, the front surface dummy stack structure FDS may vertically overlap the first transistor TR1. Specifically, the front surface dummy wires DT1 and the front surface dummy vias DV1 that constitute the front surface dummy stack structure FDS may overlap the first gate electrode GE1 of the first transistor TR1. The front surface dummy wires DT1 and the front surface dummy vias DV1 that constitute the front surface dummy stack structure FDS may overlap at least one of the eleventh or twelfth source/drain pattern SD11 or SD12. The front surface dummy stack structure FDS may overlap the first channel pattern CH1. The front surface dummy stack structure FDS may overlap the gate contact GC.

The first transistor TR1 and the first wiring structure MRS1 may partially constitute various logic circuits such as a flip-flop circuit, an inverter circuit, AND, OR, XOR, XNOR, NAND, and NOR. Heat occurring in the first transistor TR1 during testing the semiconductor device 1000 may be transferred to an upper end of the front surface dummy stack structure FDS through the front surface dummy wires DT1 and the front surface dummy vias DV1 of the front surface dummy stack structure FDS. When a failure occurs in a logic circuit to which the first transistor TR1 belongs, abnormal heat may occur in the first transistor TR1 or temperature of the first transistor TR1 may be abnormal. Accordingly, the failure of the logic circuit to which the first transistor TR1 belongs may be determined by sensing the abnormal heat or temperature on the upper end of the front surface dummy stack structure FDS. Since the front surface dummy stack structure FDS is located above the first transistor TR1 (e.g., located directly on the first transistor TR1) so as to overlap the first transistor TR1 of the logic circuit to measure the failure, a failure position may be accurately found out. Accordingly, a failure spot may be rapidly found out by increasing consistency between an actual failure spot and a heat spot.

On a cross-sectional view, each one of the front surface dummy wires DT1 and the front surface dummy vias DV1 that constitute the front surface dummy stack structure FDS may be disposed at one level like FIG. 2A. Alternatively, like FIG. 2B, the front surface dummy wires DT1 and the front surface dummy vias DV1 that constitute the front surface dummy stack structure FDS may be disposed in plurality at a predetermined level.

A bonding insulating layer (or an upper insulating layer) 210 may be disposed on the j-th front surface wiring layer FWL(J). The bonding insulating layer 210 may have a single-layered or multi-layered structure of at least one of SiO₂, SiN, or SiCN. A support substrate 200 may be disposed on the bonding insulating layer 210. The support substrate 200 may be a silicon substrate or insulating substrate. The support substrate 200 may be omitted. The bonding insulating layer 210 may be referred to as ‘a passivation layer’. The support substrate 200 and the bonding insulating layer 210 may be transparent enough to let light through. In some embodiments, the bonding insulating layer 210 may cover the first wiring structure MRS1 and the front surface dummy stack structure FDS.

Referring to FIGS. 1, 4A and 4B, the rear surface 100B of the substrate 100 may be covered by a lower insulating layer 160. The lower insulating layer 160 may have a single-layered or multi-layered structure of at least one of SiO₂, SiN, or SiON. Rear surface wiring layers BWL may be stacked under the lower insulating layer 160. The rear surface wiring layers BWL may include first to K-th rear surface wiring layers BWL(1) to BWL(K). The K may be a natural number equal to or greater than 2. The K may be smaller than the J.

Each of the rear surface wiring layers BWL may include a rear surface insulating layer BI, and rear surface vias BV and rear surface wires BT disposed therein. The rear surface insulating layer BI may have a single-layered or multi-layered structure of at least one of SiO₂, SiN, SiON, SiCN, or SiOCH. Each of the rear surface vias BV and the rear surface wires BT may include metal such as tungsten, copper, aluminum, titanium, or tantalum.

The rear surface wires BT belonging to an odd-numbered rear surface wiring layer (BWL(1), BWL(3) . . . ) among the rear surface wiring layers BWL may extend along the second direction D2. The rear surface wires BT belonging to an even-numbered rear surface wiring layer (BWL(2), BWL(4) . . . ) among the rear surface wiring layers BWL may extend along the first direction D1 crossing the second direction D2. Some of the rear surface vias BV and the rear surface wires BT may constitute a rear surface power network. Some of the rear surface vias BV and the rear surface wires BT may apply a source voltage or drain voltage to at least any one among the source/drain patterns SD11, SD12, SD21, and SD22.

Uppermost ones BT(P1), BT(P2), and BT(U) among the rear surface wires BT may have a smaller width, height, and/or pitch than a lowermost rear surface wire BT(B). A lower surface of the lowermost rear surface wire BT(B) among the rear surface wires BT may have a second level LV2. The lowermost front surface wire FT(B) among the front surface wires FT may have a smaller width, height, and/or pitch than the uppermost ones BT(P1), BT(P2), and BT(U) among the rear surface wires BT.

The lowermost rear surface wire BT(B) among the rear surface wires BT may be referred to as a conductive pad. An external connection terminal OB may penetrate a lowermost rear surface insulating layer BI(B) to be bonded to the conductive pad. The external connection terminal OB may include a conductive bump, a conductive pillar and/or a solder ball.

Referring to FIGS. 2A and 4A, some of the uppermost ones BT(P1), BT(P2), and BT(U) among the rear surface wires BT may be power wires BT(P1) and BT(P2). Rear surface contacts BSC may penetrate the substrate 100 to connect the power wires BT(P1) and BT(P2) to at least one among the source/drain patterns SD11, SD12, SD21, and SD22. For example, one among the rear surface contacts BSC may penetrate the substrate 100 to connect the power wire BT(P1) to the eleventh source/drain pattern SD11 of the first transistor TR1. Accordingly, a drain voltage VDD or a source voltage VSS may be applied to the eleventh source/drain pattern SD11. Another one among the rear surface contacts BSC may penetrate the substrate 100 to connect another power wire BT(P2) to the twenty first source/drain pattern SD21 of the second transistor TR2. Accordingly, the drain voltage VDD or the source voltage VSS may be applied to the twenty first source/drain pattern SD21.

The rear surface contacts BSC may have a conductive column shape. Each of the rear surface contacts BSC may include a contact plug PCP and a liner LIN at least surrounding a side surface thereof. The contact plug PCP may include at least one metal selected from the group consisting of tungsten, molybdenum, ruthenium, cobalt, aluminum, and copper. The liner LIN may include a silicon-based insulating material (for example, SiO, SiN, SiOC, or SiOCN).

Referring to FIG. 1, the semiconductor device 1000 may further include a through via TV penetrating the substrate 100, the first and second interlayered insulating layers 110 and 120 and the lower insulating layer 160. The through via TV may be disposed between the separation structures DB adjacent to each other. The through via TV may connect one (for example, the lowermost front surface wire FT(B)) among the front surface wires FT to one (for example, the uppermost rear surface wire BT(U)) among the rear surface wires BT. The through via TV may include at least one metal selected from the group consisting of tungsten, molybdenum, ruthenium, cobalt, aluminum, and copper.

Referring to FIG. 4A, some of the rear surface wires BT and the rear surface vias BV may constitute a third wiring structure MRS3 of FIGS. 4A and 4B. The third wiring structure MRS3 may be connected to the uppermost ones BT(P1), BT(P2) and BT(U) among the rear surface wires BT. The third wiring structure MRS3 may include the rear surface wires BT and the rear surface vias BV connected to each other.

Referring to FIG. 4A, a rear surface dummy stack structure BDS may be disposed under the rear surface 100B of the substrate 100. The rear surface dummy stack structure BDS may include rear surface dummy wires DT2 and rear surface dummy vias DV2 alternately stacked. The rear surface dummy wires DT2 and the rear surface dummy vias DV2 may vertically overlap each other. A lower surface of a lowermost rear surface dummy wire DT2(B), among the rear surface dummy wires DT2, that constitutes the rear surface dummy stack structure BDS may have a second level LV2. That is, the lower surface of the lowermost rear surface dummy wire DT2(B) may be located at the same level LV2 as the lower surface of the lowermost rear surface wire BT(B). Ones, located at the same level, among the rear surface dummy wires DT2 and the rear surface wires BT may have the same width and/or height, and may be formed of the same material. Ones, located at the same level, among the rear surface dummy vias DV2 and the rear surface vias BV may have the same width and/or height, and may be formed of the same material. The lower surface of the lowermost rear surface dummy wire DT2(B) may be covered by the lowermost rear surface insulating layer BI(B). The lowermost rear surface insulating layer BI(B) may be referred to as a passivation layer.

The rear surface dummy stack structure BDS may be electrically floated. The rear surface dummy stack structure BDS is not connected to the transistors TR1 and TR2 and the rear surface wires BT. An uppermost front surface dummy wire DT2(T), among the rear surface dummy wires DT2, that constitutes the rear surface dummy stack structure BDS may be spaced apart from one among the uppermost rear surface wires BT(P1), BT(P2), and BT(U) in a vertical direction (that is, the third direction D3), and a (only one layered) rear surface insulating layer BI(T) may be interposed between the uppermost rear surface wires BT(P1), BT(P2), and BT(U) and the uppermost rear surface dummy wire DT2(T).

Referring to FIG. 4A, the rear surface dummy stack structure BDS may vertically overlap the second transistor TR2. Specifically, the rear surface dummy wires DT2 and the rear surface dummy vias DV2 that constitute the rear surface dummy stack structure BDS may overlap the second gate electrode GE2 of the second transistor TR2. The rear surface dummy wires DT2 and the rear surface dummy vias DV2 that constitute the rear surface dummy stack structure BDS may overlap at least one of the twenty first or twenty second source/drain patterns SD21 or SD22.

The second transistor TR2 and the second wiring structure MRS2 may partially constitute various logic circuits such as a flip-flop circuit, an inverter circuit, AND, OR, XOR, XNOR, NAND, and NOR. Heat occurring in the second transistor TR2 during testing the semiconductor device 1000 may be transferred to a lower end of the rear surface dummy stack structure BDS through the rear surface dummy wires DT2 and the rear surface dummy vias DV2 of the rear surface dummy stack structure BDS. When a failure occurs in the logic circuit to which the second transistor TR2 belongs, abnormal heat may occur in the second transistor TR2 or temperature of the second transistor TR2 may be abnormal. Accordingly, the failure of the logic circuit to which the second transistor TR2 belongs may be determined by sensing the abnormal heat or temperature on the lower end of the rear surface dummy stack structure BDS. Since the rear surface dummy stack structure BDS is located below the second transistor TR2 (e.g., located directly under the second transistor TR2) so as to overlap the second transistor TR2 of the logic circuit to measure the failure, a failure position may be accurately found out. Accordingly, a failure spot may be rapidly found out by increasing consistency between an actual failure spot and a heat spot.

On a cross-sectional view, the rear surface dummy wires DT2 and the rear surface dummy vias DV2 that constitute the rear surface dummy stack structure BDS may be disposed one by one at one level like FIG. 4A. Alternatively, like FIG. 4A, the rear surface dummy wires DT2 and the rear surface dummy vias DV2 that constitute the rear surface dummy stack structure BDS may be disposed in plurality at a predetermined level.

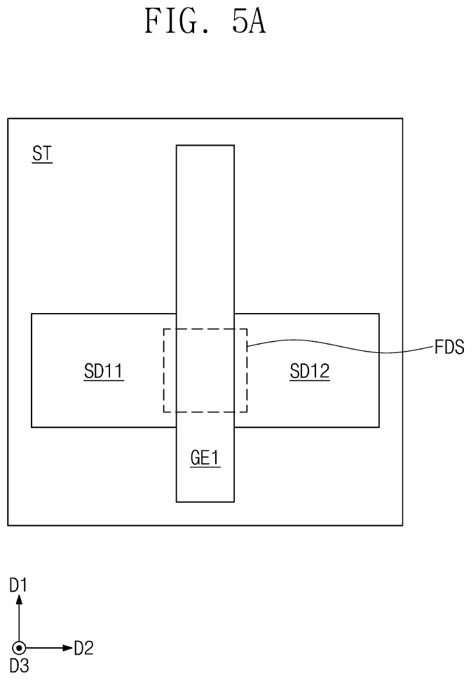

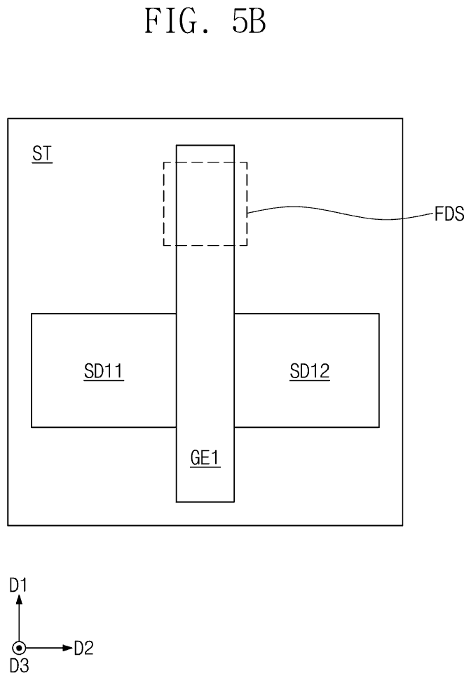

FIGS. 5A and 5B are plan views of a portion of the semiconductor device consistent with embodiments of the present disclosure.

Referring to FIGS. 5A and 5B, the first gate electrode GE1 may extend along the first direction D1 and may overlap the element separation layer ST. Like FIGS. 2A and 5A, the front surface dummy stack structure FDS may overlap one portion of the first gate electrode GE1 between the eleventh and twelfth source/drain patterns SD11 and SD12 or may overlap the first channel pattern CH1. Alternatively, like FIG. 5B, the front surface dummy stack structure FDS may overlap another portion of the first gate electrode GE1 located on the element separation layer ST. That is, the front surface dummy stack structure FDS may overlap the element separation layer ST under the first gate electrode GE1. Like the front surface dummy stack structure FDS, the rear surface dummy stack structure BDS may overlap the second gate electrode GE2 of the second transistor TR2 or the second channel pattern CH2, or may overlap the element separation layer ST under the second gate electrode GE2.

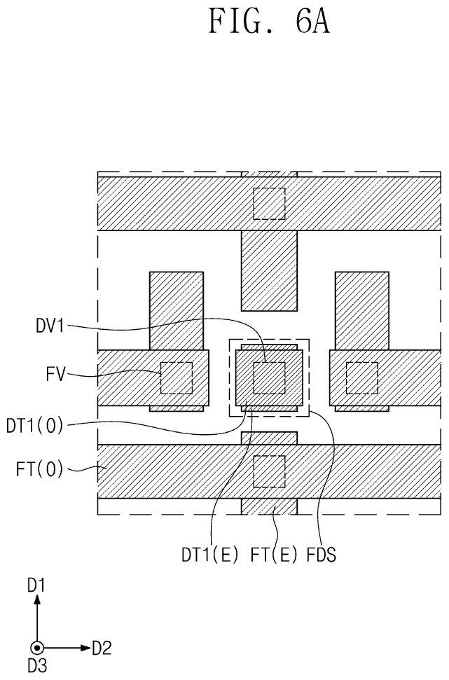

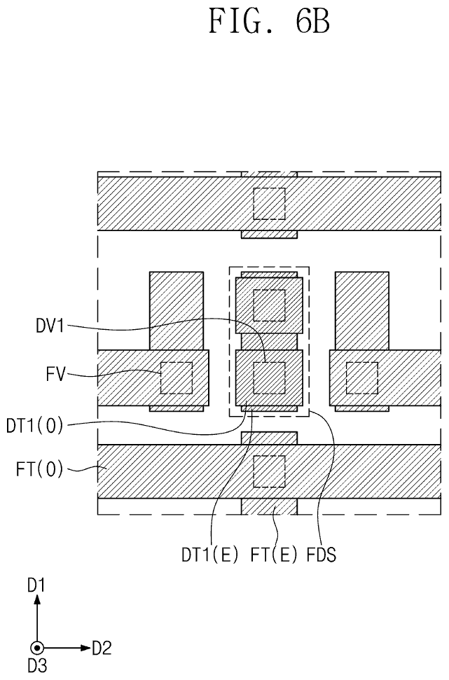

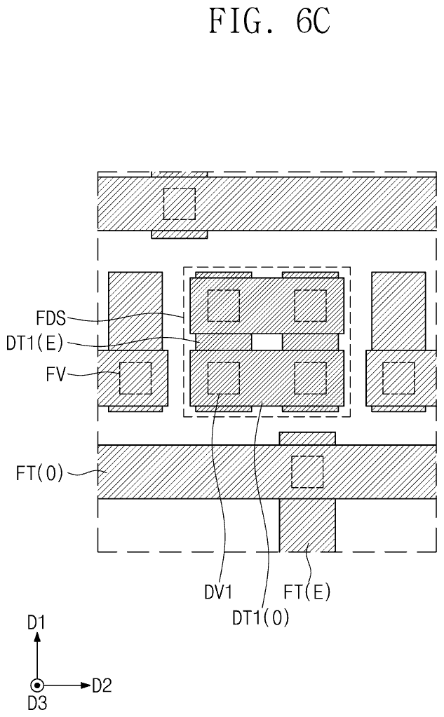

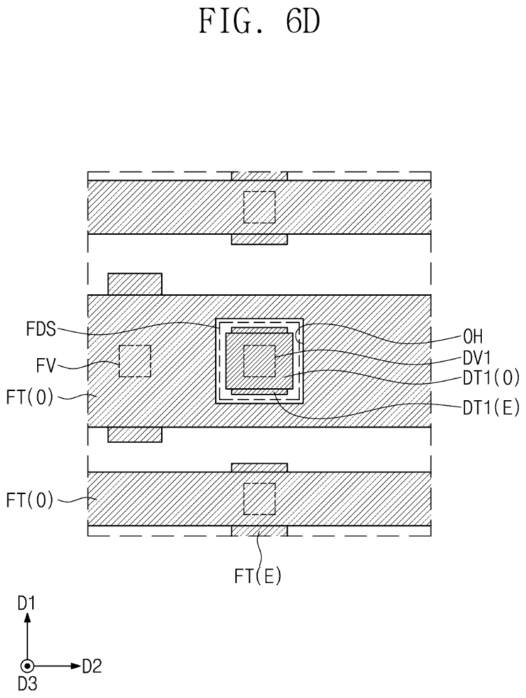

FIGS. 6A to 6D are plan views of a portion of the semiconductor device consistent with embodiments of the present disclosure.

Referring to FIGS. 6A to 6D, on a plan view, the front surface dummy stack structure FDS is disposed in an empty space in which the front surface wires FT and the front surface vias FV are not located. The front surface wires FT includes even-numbered front surface wires FT(E) and odd-numbered front surface wires FT(O). The even-numbered front surface wires FT(E) may extend in the first direction D1. The odd-numbered front surface wires FT(O) may extend in the second direction D2. The front surface dummy wires DT1 included in the front surface dummy stack structure FDS include even-numbered front surface dummy wires DT1(E) and odd-numbered front surface dummy wires DT1(O). Like FIG. 6A, the front surface dummy wires DT1 may be connected to only one by one at a predetermined level.

Like FIGS. 6B and 6C, the even-numbered front surface dummy wires DT1(E) may extend in the first direction D1. A plurality of odd-numbered front surface dummy wires DT1(O) may be connected to one even-numbered front surface dummy wire DT1(E). Like FIG. 6C, the odd-numbered front surface dummy wires DT1(O) may extend in the second direction D2.

Alternatively, referring to FIG. 6D, at least one among the odd-numbered front surface wires FT(O) may have a hole OH. The front surface dummy stack structure FDS may be at least partially inserted into the hole OH.

Disposition between the rear surface dummy stack structure BDS and the rear surface wires BT may be the same as/similar to the disposition between the front surface dummy stack structure FDS and the front surface wires FT described with reference to FIGS. 6A to 6D.

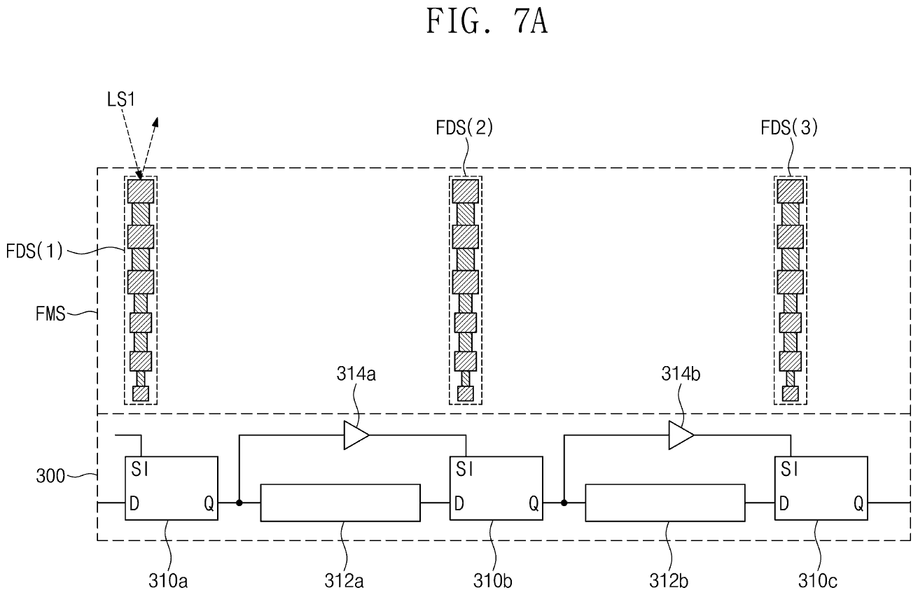

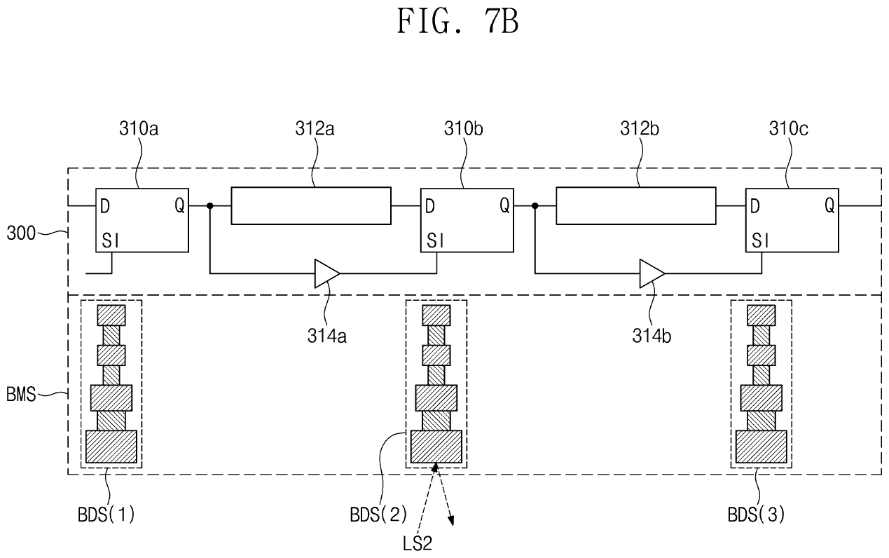

FIGS. 7A and 7B are conceptual diagrams of the semiconductor device consistent with embodiments of the present disclosure.

Referring to FIG. 7A, the semiconductor device according to the present embodiment may include a circuit portion 300 and a front surface structure FMS disposed thereon. The circuit portion 300 may include flip-flop circuits 310a, 310b and 310c, buffers 314a and 314b, and cells 312a and 312b connected to each other. The flip-flop circuits 310a, 310b and 310c, the buffers 314a and 314b and the cells 312a and 312b may constitute a scan chain. Each of the cells 312a and 312b may be a logic cell and/or a memory cell. Each of the buffers 314a and 314b may include an inverter. In some embodiments, each of the flip-flop circuits 310a, 310b and 310c may be disposed on the front surface 100F of the substrate 100.

Each of the flip-flop circuits 310a, 310b and 310c may include an output terminal Q, a functional input terminal D and a test input terminal SI to which a test signal is input. Each of the flip-flop circuits 310a, 310b, and 310c may include the first and second transistors TR1 and TR2 and wiring structures MRS1 to MRS3 described with reference to FIGS. 1 to 4B. The test input terminal SI may correspond to at least one of the gate electrodes GE1 or GE2 of the first and second transistors TR1 and TR2. That is, the test signal may be input to at least one of the gate electrodes GE1 or GE2 of FIGS. 1 to 4B.

The front surface structure FMS may include the front surface dummy stack structure FDS described with reference to FIGS. 1 to 6D. Each of the front surface dummy stack structures FDS may not be electrically connected to any one among the flip-flop circuits 310a, 310b, and 310c, the buffers 314a and 314b, and the cells 312a and 312b, and may be electrically floated.

The front surface dummy stack structure FDS may be provided in plurality. The front surface dummy stack structures FDS may be respectively disposed on the test input terminals SI of the flip-flop circuits 310a, 310b, and 310c. For example, a first front surface dummy stack structure FDS(1) is disposed on the test input terminal SI of the first flip-flop circuit 310a. A second front surface dummy stack structure FDS(2) is disposed on the test input terminal SI of the second flip-flop circuit 310b. A third front surface dummy stack structure FDS(3) is disposed on the test input terminal SI of the third flip-flop circuit 310c.

When the semiconductor device is tested so that a failure occurs in any one of the cells 312a and 312b, temperature of the test input terminal SI of one, among the flip-flop circuits 310a, 310b, and 310c, adjacent thereto may change. Accordingly, temperature of the front surface dummy stack structure FDS disposed thereon may change. In some embodiments, the failure of the semiconductor device may be determined by irradiating an upper end of the front surface dummy stack structure FDS with first laser LS1 and sensing a change of the temperature on the upper end of the front surface dummy stack structure FDS and a reflection coefficient of the reflected laser.

Referring to FIG. 7B, the semiconductor device according to an embodiment may include the circuit portion 300 and a rear surface structure BMS disposed thereunder. The circuit portion 300 may be the same as what is described with reference to FIG. 7A. The rear surface structure BMS may include the rear surface dummy stack structure BDS described with reference to FIGS. 1 to 6D. Each of the rear surface dummy stack structures BDS may not be electrically connected to any one among the flip-flop circuits 310a, 310b, and 310c, the buffers 314a and 314b, and the cells 312a and 312b, and may be electrically floated.

The rear surface dummy stack structure BDS may be provided in plurality. The rear surface dummy stack structures BDS may be respectively disposed under the test input terminals SI of the flip-flop circuits 310a, 310b, and 310c. For example, a first rear surface dummy stack structure BDS(1) is disposed under the test input terminal SI of the first flip-flop circuit 310a. A second rear surface dummy stack structure BDS(2) is disposed under the test input terminal SI of the second flip-flop circuit 310b. A third rear surface dummy stack structure BDS(3) is disposed under the test input terminal SI of the third flip-flop circuit 310c.

In some embodiments, similar to what is described above, when the semiconductor device is tested, the failure of the semiconductor device may be determined by irradiating a lower end of the rear surface dummy stack structure BDS with second laser LS2 and sensing a change of temperature of the lower end of the rear surface dummy stack structure BDS and a reflection coefficient of the reflected laser.

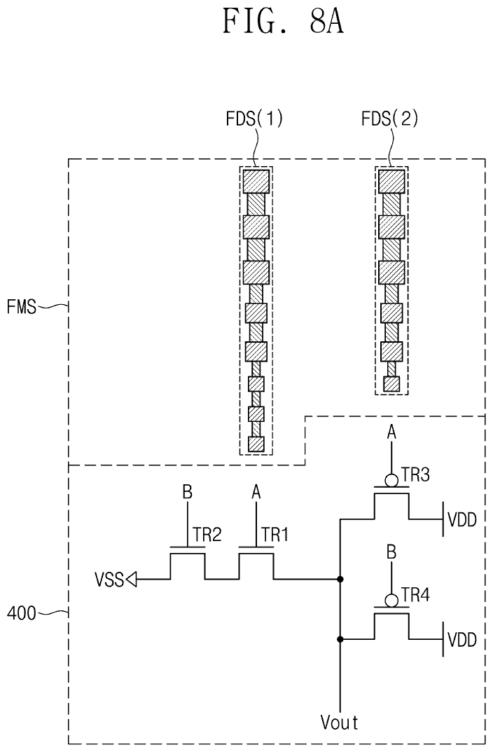

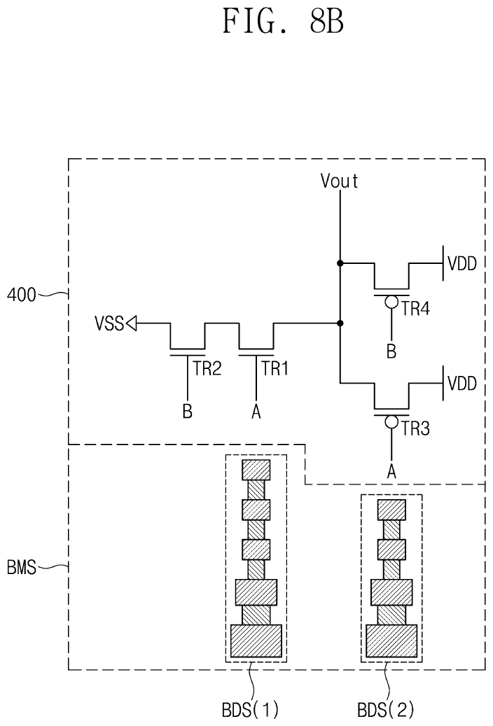

FIGS. 8A and 8B are conceptual diagrams of the semiconductor device consistent with embodiments of the present disclosure.

Referring to FIG. 8A, the semiconductor device according to an embodiment may include a circuit portion 400 and the front surface structure FMS disposed thereon. The circuit portion 400 may include first to fourth transistors TR1 to TR4 connected to each other. The first and second transistors TR1 and TR2 may be NMOSFETs. The third and fourth transistors TR3 and TR4 may be PMOSFETs. The drain voltage VDD may be applied to one terminal of the third and fourth transistors TR3 and TR4. The source voltage VSS may be applied to one terminal of the second transistor TR2. A first signal A may be identically input to gate electrodes of the first and third transistors TR1 and TR3. A second signal B may be identically input to gate electrodes of the second and fourth transistors TR2 and TR4.

The front surface structure FMS may include the front surface dummy stack structure FDS described with reference to FIGS. 1 to 6D. Each of the front surface dummy stack structures FDS may not be electrically connected to any one among the first to fourth transistors TR1 to TR4, and may be electrically floated.

The front surface dummy stack structure FDS may be provided in plurality. The front surface dummy stack structures FDS may be respectively disposed on the first and third transistors TR1 and TR3. For example, a first front surface dummy stack structure FDS(1) is disposed on the first transistor TR1. A second front surface dummy stack structure FDS(2) is disposed on the third transistor TR3. The first front surface dummy stack structure FDS(1) may have the same vertical length as or a different vertical length from the second front surface dummy stack structure FDS(2). The first front surface dummy stack structure FDS(1) may have the same upper end level as the second front surface dummy stack structure FDS(2). In some embodiments, an output voltage Vout may be output to outside of the circuit portion 400.

Referring to FIG. 8B, the semiconductor device according to an embodiment may include the circuit portion 400 and the rear surface structure BMS disposed thereunder. The circuit portion 400 may be the same as what is described with reference to FIG. 8A. The rear surface structure BMS may include the rear surface dummy stack structures BDS described with reference to FIGS. 1 to 6D. Each of the rear surface dummy stack structures BDS may not be electrically connected to any one among the first to fourth transistors TR1 to TR4, and may be electrically floated.

The rear surface dummy stack structure BDS may be provided in plurality. The rear surface dummy stack structures BDS may be respectively disposed under the first and third transistors TR1 and TR3. For example, a first rear surface dummy stack structure BDS(1) is disposed under the first transistor TR1. A second rear surface dummy stack structure BDS(2) is disposed under the third transistor TR3. The first rear surface dummy stack structure BDS(1) may have the same vertical length as or a different vertical length from the second rear surface dummy stack structure BDS(2). The first rear surface dummy stack structure BDS(1) may have the same lower end level as the second rear surface dummy stack structure BDS(2).

Referring to FIGS. 7A to 8B, a circuit structure included in the circuit portions 300 and 400 is exemplarily described, but the scope of the present disclosure is not limited thereto. The front surface dummy stack structure FDS and the rear surface dummy stack structure BDS may be disposed on a spot (for example, a gate electrode or wire connection portion) in which the failure needs to be detected and will be measured in any circuit.

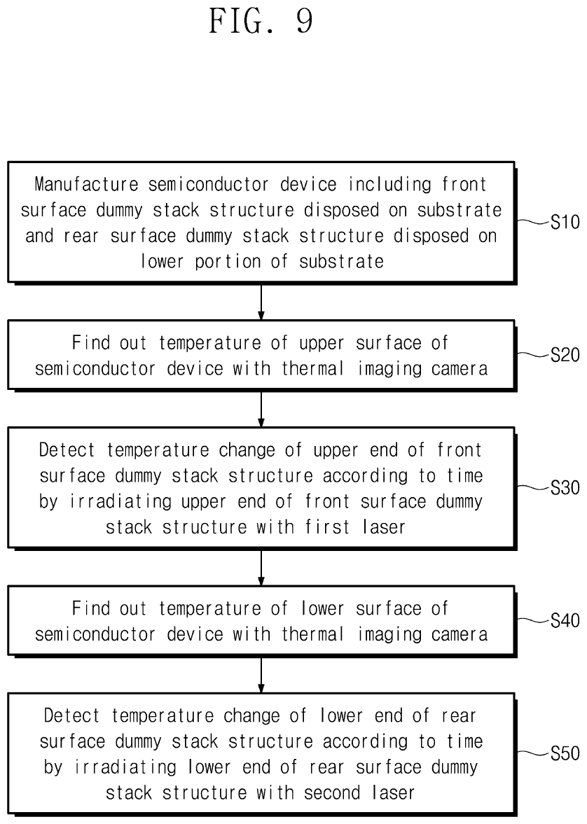

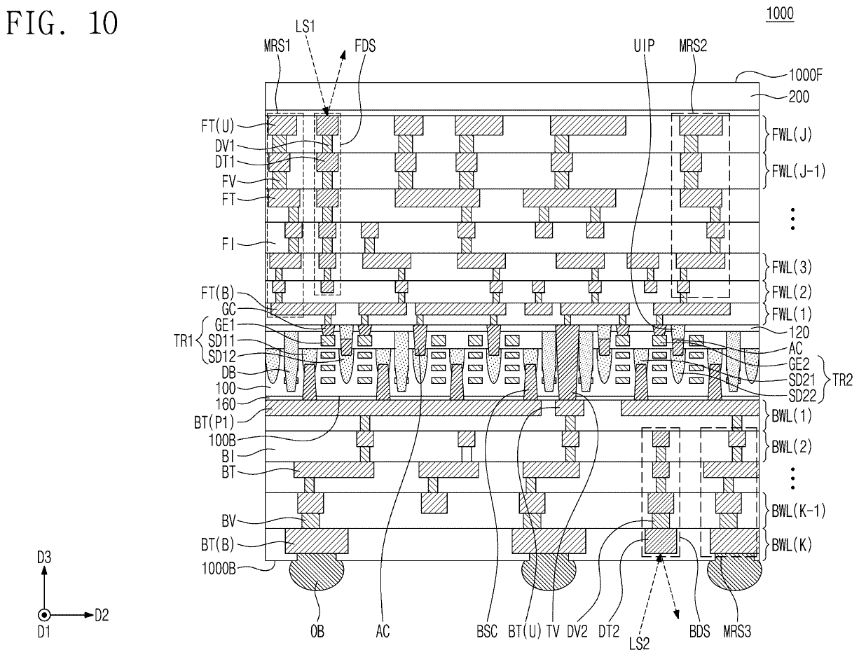

FIG. 9 is a flowchart illustrating a method for analyzing a failure of a semiconductor device consistent with some embodiments of the present disclosure. FIG. 10 is a schematic diagram illustrating the method for analyzing a failure of a semiconductor device consistent with some embodiments of the present disclosure.

Referring to FIGS. 9 and 10, first, a semiconductor device 1000 described with reference to FIGS. 1 to 8B is manufactured (a first operation, S10). The semiconductor device 1000 may be a wafer structure, of a wafer level, before a sawing process and bonding the external connection terminal OB thereto. The wafer structure may include a plurality of device regions and a scribe lane region therebetween. Each of the device regions of the wafer structure may have a structure of the semiconductor device 1000 described with reference to FIGS. 1 to 8B. The semiconductor device 1000 may include at least one front surface dummy stack structure FDS disposed on the front surface 100F, and at least one rear surface dummy stack structure BDS disposed under the rear surface 100B, of the substrate 100. The semiconductor device 1000 may be manufactured using typical semiconductor manufacturing processes. However, when the front surface vias FV and the front surface wires FT are formed, the front surface dummy vias DV1 and the front surface dummy wires DT1 may be simultaneously formed. In addition, when the rear surface wires BT and the rear surface vias BV are formed, the rear surface dummy wires DT2 and the rear surface dummy vias DV2 may be simultaneously formed.

Temperature distribution of an upper surface 1000F of the semiconductor device 1000 is captured/found out with a thermal imaging camera (a second operation, S20). In this case, an abnormal spot may be found out in the temperature distribution of the upper surface 1000F of the semiconductor device 1000. The abnormal spot may correspond to at least one among the front surface dummy stack structures FDS.

A temperature change of an upper end of the front surface dummy stack structure FDS according to time is detected by irradiating an upper end of the front surface dummy stack structure FDS located on the abnormal spot with the first laser LS1 (a third operation, S30). The third operation (S30) may be performed by using at least one of an optical probed thermos-reflectance image mapping (OPTIM) apparatus or a photon emission microscopy (PEM) apparatus. When the third operation (S30) is performed, a reflection coefficient of the laser reflected from a lower end of the rear surface dummy stack structure BDS may be detected. Accordingly, the failure of the semiconductor device 1000 may be detected and analyzed.

Temperature distribution of a lower surface 1000B of the semiconductor device 1000 is captured/found out with the thermal imaging camera (a fourth operation, S40). In this case, an abnormal spot may be found out in the temperature distribution of the lower surface 1000B of the semiconductor device 1000. The abnormal spot may correspond to at least one among the rear surface dummy stack structures BDS.

A temperature change of a lower end of the rear surface dummy stack structure BDS according to time is detected by irradiating the lower end of the rear surface dummy stack structure BDS located on the abnormal spot with the second laser LS2 (a fifth operation, S50). The fifth operation (S50) may be performed by using at least one of the optical probed thermos-reflectance image mapping (OPTIM) apparatus or the photon emission microscopy (PEM) apparatus. When the fifth operation (S50) is performed, the reflection coefficient of the laser reflected from a lower end of the rear surface dummy stack structure BDS may be detected. Accordingly, the failure of the semiconductor device 1000 may be detected and analyzed.

As the semiconductor device is highly integrated and refined, there is limitation in the method for analyzing a failure in an optical manner such as optical fault isolation (OFI). In addition, it is difficult to apply a method such as e-beam (or electrical) fault isolation (EFI) in which a failure of a transistor is found out by irradiating a rear surface of the semiconductor substrate with laser, to the semiconductor device having a back-side power delivery network (BSPDN) structure. However, in some embodiments, the failure may be detected by disposing a front surface dummy stack structure and a rear surface dummy stack structure adjacently to a spot, in which the failure should be detected, of the semiconductor device. Accordingly, an accurate failure position may be found out without partially removing the semiconductor device, and a type and a cause thereof may be analyzed by sensing a temperature change according to time.

In some embodiments, since a front surface dummy stack structure and a rear surface dummy stack structure for measuring heat emission are disposed adjacent to a spot, in which a failure should be detected, of a semiconductor device, a failure spot may be rapidly found out by increasing consistency between an actual failure spot and a heat spot. Accordingly, the semiconductor device in which the failure is easily analyzed may be provided. A method for analyzing a failure of a semiconductor device consistent with the present disclosure has an improved consistency.

Although the embodiments consistent with the present disclosure have been described with reference to the accompanying drawings, it is understood that the present disclosure should not be limited to these embodiments but various changes and modifications can be made by one ordinary skilled in the art within the spirit and scope of the present disclosure as hereinafter claimed. Therefore, it should be understood that the embodiments described above are exemplary in all respects and are not intended to be limiting. The embodiments of FIGS. 1 to 10 may be combined with each other.

1. A semiconductor device comprising:
a substrate including a front surface and a rear surface disposed opposed to the front surface along a vertical direction of the semiconductor device;
a first transistor disposed on the front surface of the substrate and including a first gate electrode and first source/drain patterns disposed adjacent to the first gate electrode along a direction perpendicular to the vertical direction; and
a front surface dummy stack structure disposed on the first transistor and electrically floated, the front surface dummy stack structure extending from a lower end to an upper end along the vertical direction, the lower end being spaced apart from the first transistor in the vertical direction,
wherein the front surface dummy stack structure includes a plurality of front surface dummy vias and a plurality of front surface dummy wires, the plurality of front surface dummy vias and the plurality of front surface dummy wires being alternately stacked, and
the plurality of front surface dummy vias and the plurality of front surface dummy wires of the front surface dummy stack structure overlap the first gate electrode in a vertical direction.

2. The semiconductor device of claim 1, further comprising:
a first wiring structure connected to one of the first source/drain patterns and the first gate electrode; and
an upper insulating layer covering the first wiring structure and the front surface dummy stack structure,
wherein the first wiring structure includes a plurality of front surface vias and a plurality of front surface wires, and
an upper end of the first wiring structure is disposed at a same level along the vertical direction as the upper end of the front surface dummy stack structure.

3. The semiconductor device of claim 2, wherein an uppermost front surface wire of the plurality of front surface wires does not overlap the plurality of front surface dummy vias and the plurality of front surface dummy wires in the vertical direction.

4. The semiconductor device of claim 2, further comprising a support substrate on the upper insulating layer.

5. The semiconductor device of claim 1, wherein the first transistor is included in a first flip-flop circuit.

6. The semiconductor device of claim 5, wherein the first gate electrode of the first transistor is configured to receive a test signal input.

7. The semiconductor device of claim 1, further comprising:
a power wire disposed on the rear surface of the substrate,
wherein the power wire is connected to one of the first source/drain patterns of the first transistor.

8. The semiconductor device of claim 1, further comprising:
a second transistor that is disposed on the front surface of the substrate and includes a second gate electrode and second source/drain patterns adjacent to the second gate electrode;
a first power wire disposed on the rear surface of the substrate and connected to one of the second source/drain patterns; and
a rear surface dummy stack structure disposed on the rear surface of the substrate and electrically floated, the rear surface dummy stack structure extending from a lower end to an upper end along the vertical direction, the upper end being spaced apart from the second transistor in the vertical direction,
wherein the rear surface dummy stack structure includes a plurality of rear surface dummy vias and a plurality of rear surface dummy wires, the plurality of rear surface dummy vias and the plurality of rear surface dummy wires being alternately stacked, and
the plurality of rear surface dummy vias and the plurality of rear surface dummy wires of the rear surface dummy stack structure overlap the second gate electrode in the vertical direction.

9. The semiconductor device of claim 8, further comprising:
a second wiring structure that is disposed on the rear surface of the substrate and connected to the first power wire,
wherein the second wiring structure includes a plurality of rear surface vias and a plurality of rear surface wires, the plurality of rear surface vias and the plurality of rear surface wires being alternately stacked, and
a lower end of the second wiring structure is disposed at a same level along the vertical direction as the lower end of the rear surface dummy stack structure.

10. The semiconductor device of claim 9, further comprising:
a rear surface insulating layer that is disposed on the rear surface of the substrate and covering the lower end of the second wiring structure and the lower end of the rear surface dummy stack structure; and
an external connection terminal penetrating the rear surface insulating layer to be connected to the lower end of the second wiring structure.

11. The semiconductor device of claim 8, wherein the second transistor is included in a second flip-flop circuit.

12. The semiconductor device of claim 11, wherein the second gate electrode of the second transistor is configured to receive a test signal input.

13. The semiconductor device of claim 1, wherein an uppermost front surface dummy wire of the plurality of front surface dummy wires has a width greater than a width of a lowermost front surface dummy wire of the plurality of front surface dummy wires.

14. A semiconductor device comprising:
a substrate including a front surface and a rear surface opposed to the front surface along a vertical direction of the semiconductor device;
a first transistor that is disposed on the front surface of the substrate and includes a first gate electrode and first source/drain patterns adjacent to the first gate electrode;
a first power wire that is disposed on the rear surface of the substrate and connected to one of the first source/drain patterns; and
a rear surface dummy stack structure disposed on the rear surface of the substrate and electrically floated, the rear surface dummy stack structure extending from a lower end to an upper end along the vertical direction, the upper end being spaced apart from the first transistor in the vertical direction,
wherein the rear surface dummy stack structure includes a plurality of rear surface dummy vias and a plurality of rear surface dummy wires, the plurality of rear surface dummy vias and the plurality of rear surface dummy wires being alternately stacked, and
the plurality of rear surface dummy vias and the plurality of rear surface dummy wires of the rear surface dummy stack structure overlap the first gate electrode in the vertical direction.

15. The semiconductor device of claim 14, wherein the first transistor is included in a first flip-flop circuit.

16. The semiconductor device of claim 15, wherein the first gate electrode of the first transistor is configured to receive a test signal input.

17. The semiconductor device of claim 14, further comprising a first wiring structure that is disposed on the rear surface of the substrate and connected to the first power wire,
wherein the first wiring structure includes a plurality of rear surface vias and a plurality of rear surface wires, the plurality of rear surface vias and the plurality of rear surface wires being alternately stacked, and
a lower end of the first wiring structure is disposed at a same level along the vertical direction as the lower end of the rear surface dummy stack structure.

18. The semiconductor device of claim 17, further comprising:
a rear surface insulating layer that is disposed on the rear surface of the substrate and covers the lower end of the first wiring structure and the lower end of the rear surface dummy stack structure; and
an external connection terminal penetrating the rear surface insulating layer to be connected to the lower end of the first wiring structure.

19. A semiconductor device comprising:
a substrate including a front surface and a rear surface opposed to the front surface along a vertical direction of the semiconductor device;
a first flip-flop circuit and a second flip-flop circuit disposed on the front surface of the substrate, wherein the first flip-flop circuit comprises a first transistor that is disposed on the front surface of the substrate and includes a first gate electrode and first source/drain patterns adjacent to the first gate electrode, and wherein the second flip-flop circuit comprises a second transistor that is disposed on the front surface of the substrate and includes a second gate electrode and second source/drain patterns adjacent to the second gate electrode;
a front surface dummy stack structure disposed on the first transistor and electrically floated, the front surface dummy stack structure extending from a lower end to an upper end along the vertical direction, the lower end being spaced apart from the first transistor in the vertical direction;
a first wiring structure disposed on the front surface of the substrate and connected to one of the first source/drain patterns and the first gate electrode;
a first power wire disposed on the rear surface of the substrate and connected to one of the second source/drain patterns;
a rear surface dummy stack structure disposed on the rear surface of the substrate and electrically floated; and
a second wiring structure disposed on the rear surface of the substrate and connected to the first power wire,
wherein the front surface dummy stack structure includes a plurality of front surface dummy vias and a plurality of front surface dummy wires, the plurality of front surface dummy vias and the plurality of front surface dummy wires being alternately stacked,
the plurality of front surface dummy vias and the plurality of front surface dummy wires of the front surface dummy stack structure overlap the first gate electrode in the vertical direction,
the rear surface dummy stack structure includes a plurality of rear surface dummy vias and a plurality of rear surface dummy wires, the plurality of rear surface dummy vias and the plurality of rear surface dummy wires being alternately stacked, and
the plurality of rear surface dummy vias and the plurality of rear surface dummy wires of the rear surface dummy stack structure overlap the second gate electrode in the vertical direction.

20. The semiconductor device of claim 19, wherein the first wiring structure comprises a plurality of front surface vias and a plurality of front surface wires, the plurality of front surface vias and the plurality of front surface wires being alternately stacked,
an upper end of the first wiring structure is disposed at a same first level along the vertical direction as the upper end of the front surface dummy stack structure,
an uppermost front surface wire of the plurality of front surface wires does not overlap the plurality of front surface dummy wires in a vertical direction,
the second wiring structure comprises a plurality of rear surface vias and a plurality of rear surface wires, the plurality of rear surface vias and the plurality of rear surface wires being alternately stacked,
a lower end of the second wiring structure is disposed at a same second level along the vertical direction as a lower end of the rear surface dummy stack structure, and
a lowermost rear surface wire of the plurality of rear surface wires does not overlap the plurality of rear surface dummy wires in a vertical direction.

21-23. (canceled)
